(19) United States
(12) Patent Application Publication
(10) Pub. No.: US 2025/0273507 A1
(43) Pub. Date: Aug. 28, 2025

(54) MEMBER FOR SEMICONDUCTOR MANUFACTURING EQUIPMENT

(71) Applicant: NGK INSULATORS, LTD., Nagoya-Shi (JP)

(72) Inventors: Masaki ISHIKAWA, Handa-Shi (JP); Tatsuya KUNO, Nagoya-Shi (JP); Taro USAMI, Ginan-Cho (JP); Natsuki HIRATA, Nagoya-Shi (JP); Yusuke OGISO, Nagakute-Shi (JP); Hideaki HASHIMOTO, Nisshin-Shi (JP)

(73) Assignee: NGK INSULATORS, LTD., Nagoya-Shi (JP)

(21) Appl. No.: 18/814,783

(22) Filed: Aug. 26, 2024

Related U.S. Application Data
(63) Continuation of application No. PCT/JP2024/006631, filed on Feb. 22, 2024.

(51) Int. Cl. H01L 21/687

(52) U.S. Cl. CPC H01L 21/68785; H01L 21/68757

(57) ABSTRACT

A member for a semiconductor manufacturing equipment that uses a discharge suppression technology different from conventional ones is provided. A member for a semiconductor manufacturing equipment includes: a ceramic substrate having an upper surface on which a wafer is to be placed and a lower surface; a plug placement hole that vertically penetrates the ceramic substrate; and a plug embedded in the plug placement hole; wherein the plug is composed of a dense body, including an upper end surface exposed on a side of the upper surface, a lower end surface exposed on a side of the lower surface, and a gas passage; and wherein a maximum height D₁ in the vertical direction from the upper end opening to a surface of the gas passage, and a maximum height D₂ from the lower end opening to the surface of the gas passage satisfies a relationship: D₁<D₂.

### CROSS REFERENCE TO RELATED APPLICATIONS

The present invention claims the benefit of priority to International Patent Application PCT/JP2024/6631 filed on Feb. 22, 2024 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer, which is the object to be adsorbed.

An example of a known member for semiconductor manufacturing equipment includes a ceramic substrate having an upper surface on which a wafer is to be placed, a gas passage portion that vertically penetrates the ceramic substrate, and a conductive base plate bonded to the lower surface of the ceramic substrate. At the time of wafer processing, cooling gas such as helium gas is introduced into the back surface of the wafer through a gas passage portion.

In such a member for a semiconductor manufacturing equipment, a large potential difference the wafer may occur, and discharge (insulation breakdown) may occur between the wafer and the base plate via the gas passage portion. For this reason, various techniques for arranging plugs in a gas passage portion have been studied in order to suppress discharge. Plugs are often composed of porous materials. If there is no plug, for example, when gas molecules are ionized by the application of an RF voltage, the generated electrons are accelerated and collide with other gas molecules, causing a glow discharge and eventually an arc discharge. However, if there is a plug, it suppresses the discharge because the electrons hit the plug before colliding with other gas molecules.

Patent Literature 1 proposes a plug having a gas flow passage section that penetrates in flexion a dense main body portion in the thickness direction. It has also been proposed that at least a portion of the entire length of the gas flow passage section be made porous and insulating.

Patent Literature 2 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the ceramic dielectric substrate has a first main surface and a first hole portion located between the first main surface and the first porous portion; the first porous portion has a porous portion having a plurality of pores, and a first dense portion that is denser than the porous portion; and configured such that when projected onto a plane perpendicular to a first direction from the base plate to the ceramic dielectric substrate, the first dense portion and the first hole portion overlap, but the porous portion and the first hole portion do not overlap.

Patent Literature 3 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the first porous portion has a plurality of sparse portions having a plurality of pores, and a dense portion having a density higher than the density of the sparse portion; each of the plurality of sparse portions extends in a first direction from the base plate toward the ceramic dielectric substrate; the dense portion is located among the plurality of sparse portions; the sparse portion has the holes and a wall portion provided among the holes; and in a second direction substantially perpendicular to the first direction, the minimum dimension of the wall portion is smaller than the minimum dimension of the dense portion.

Patent Literature 4 describes an invention that aims to provide a holding device that can control the temperature of an object with high accuracy while reducing the occurrence of abnormal discharge. Specifically, it describes a holding device comprising a ceramic substrate having a first surface that holds an object and a second surface located on the opposite side of the first surface; a base member disposed on the second surface side of the ceramic substrate, the base member having a third surface located on the opposite side of the ceramic substrate; and a bonding material disposed between the ceramic substrate and the base member; wherein (1) a passage is formed in the ceramic substrate and the base member to allow fluid to communicate between an outflow hole provided on the first surface and an inflow hole provided on the third surface, or (2) a passage is formed in the ceramic substrate to enable fluid to communicate between an outflow hole provided on the first surface and an inflow hole provided on the second surface; wherein the passage is provided with a porous ceramic region and the porous ceramic region comprises a sparse region and a dense region having a lower porosity than the sparse region and disposed closer to the first surface than the sparse region.

Patent Literature 5 discloses a wafer placement table in which an insulating first porous portion disposed within the through hole of the ceramic plate, and an insulating second porous portion fitted into a recess provided on the ceramic plate side of the base plate so as to face the first porous portion are provided. The gas supplied to the gas introduction path passes through the second porous portion and the first porous portion, flows into the space between the wafer placement surface and the wafer, and is used to cool the object. It is described that due to the presence of the first porous portion and the second porous portion, it is possible to suppress the occurrence of electrical discharge (arc discharge) caused by plasma upon processing wafers while ensuring the gas flow rate from the gas introduction passage to the wafer placement surface.

### PRIOR ART

### Patent Literature

[Patent Literature 1] Japanese Patent Application Publication No. 2022-119338
[Patent Literature 2] Japanese Patent Application Publication No. 2022-31333
[Patent Literature 3] Japanese Patent Application Publication No. 2019-165194
[Patent Literature 4] Japanese Patent Application Publication No. 2022-176701
[Patent Literature 5] Japanese Patent Application Publication No. 2020-72262

### SUMMARY OF THE INVENTION

As described above, various techniques have been proposed for semiconductor manufacturing equipment members to improve the structure in the vicinity of a plug disposed in a gas passage portion that vertically penetrates a ceramic substrate in order to suppress the electrical discharge that occurs between the wafer and the base plate. However, discharge is likely to occur in wafer processing such as deep etching in which high-power plasma is used. For this reason, measures against discharge are required more than ever before.

Therefore, it is desirable to develop a new discharge suppression technology. By combining such a new discharge suppression technology with the conventional discharge suppression technology, a further discharge suppression effect can also be expected. Therefore, an object of an embodiment of the present invention is to provide a member for a semiconductor manufacturing equipment that uses a discharge suppression technology different from conventional ones.

The present inventor has made extensive studies to solve the above problems, and has created the present invention as exemplified below.

### [Aspect 1]

A member for a semiconductor manufacturing equipment, comprising:
a ceramic substrate having an upper surface on which a wafer is to be placed and a lower surface; a plug placement hole that vertically penetrates the ceramic substrate; and a plug embedded in the plug placement hole;
wherein the plug is composed of a dense body, comprising an upper end surface exposed on a side of the upper surface, a lower end surface exposed on a side of the lower surface, and a gas passage that penetrates an inside of the dense body and extends from an upper end opening provided on the upper end surface to a lower end opening provided on the lower end surface; and
wherein a maximum height D₁ in the vertical direction from the upper end opening to a surface of the gas passage, and a maximum height D₂ in the vertical direction from the lower end opening to the surface of the gas passage satisfies a relationship: D₁<D₂.

### [Aspect 2]

The member for a semiconductor manufacturing equipment according to aspect 1, wherein a relationship: 0.1≤D₁/D₂≤0.9 is satisfied.

### [Aspect 3]

The member for a semiconductor manufacturing equipment according to aspect 1 or 2, wherein the maximum height D₁ is 10 to 300 μm.

### [Aspect 4]

The member for a semiconductor manufacturing equipment according to any one of aspect 1 to 3, wherein the maximum height D₂ is 50 to 500 μm.

### [Aspect 5]

The member for a semiconductor manufacturing equipment according to any one of aspect 1 to 4, wherein taking a coordinate axis in the vertical direction, and assuming a coordinate of the upper end surface of the plug is 0, and a coordinate value of the lower end surface is H, a height D of the gas passage in the vertical direction satisfies a relationship: D≥1.5 D₁ at least within a range of coordinate value from 0.5×H to 1.0×H.

### [Aspect 6]

The member for a semiconductor manufacturing equipment according to aspect 5, wherein the height D of the gas passage in the vertical direction satisfies a relationship: D₁≤D<1.5 D₁ at least within a range of coordinate value from 0 to less than 0.1×H.

### [Aspect 7]

The member for a semiconductor manufacturing equipment according to any one of aspect 1 to 6, wherein the plug comprises a plurality of gas passages, and for all of the plurality of gas passages, the relationship D₁<D₂ is satisfied.

### [Aspect 8]

The member for a semiconductor manufacturing equipment according to aspect 1 any one of aspect 1 to 7, wherein a fracture toughness (KIC) of a portion of the plug composed of the dense body is larger than a fracture toughness (KIC) of the ceramic substrate.

### [Aspect 9]

A member for a semiconductor manufacturing equipment, comprising:
a ceramic substrate having an upper surface on which a wafer is to be placed and a lower surface; a plug placement hole that vertically penetrates the ceramic substrate; and a plug embedded in the plug placement hole;
wherein the plug is composed of a dense body, comprising an upper end portion having an upper end surface exposed on a side of the upper surface, a lower end surface exposed on a side of the lower surface, and a gas passage that penetrates an inside of the dense body and extends from a side surface opening provided on a side surface of the upper end portion to a lower end opening provided on the lower end surface.

### [Aspect 10]

The member for a semiconductor manufacturing equipment according to aspect 9, wherein a concave portion is formed on the upper surface on which a wafer is to be placed, and the upper end portion of the plug protrudes from a bottom of the concave portion such that the side surface opening is exposed.

### [Aspect 11]

The member for a semiconductor manufacturing equipment according to aspect 9 or 10, wherein a height D of the gas passage in the vertical direction is 10 to 300 μm.

### [Aspect 12]

The member for a semiconductor manufacturing equipment according to any one of aspect 9 to 11, wherein a fracture toughness (KIC) of a portion of the plug composed of the dense body is larger than a fracture toughness (KIC) of the ceramic substrate.

### [Aspect 13]

The member for a semiconductor manufacturing equipment according to any one of aspect 9 to 12, wherein the plug comprises a plurality of gas passages, and each of the plurality of gas passages is a gas passage that penetrates the inside of the dense body and extends from the side surface opening provided on the side surface of the upper end portion to the lower end opening provided on the lower end surface.

A member for a semiconductor manufacturing equipment according to an embodiment of the present invention is effective in suppressing the discharge generated between the wafer and the base plate.

### BRIEF DESCRIPTION OF THE DRAWINGS

FIG. 1-1 is a schematic vertical cross-sectional view of the member for a semiconductor manufacturing equipment according to the first embodiment of the present invention.

FIG. 1-2 is a schematic vertical cross-sectional view through a center axis of a plug that the member for a semiconductor manufacturing equipment according to the first embodiment of the present invention has (where a single gas passage is provided).

FIG. 1-3 is a schematic plan view of the plug that the member for a semiconductor manufacturing equipment according to the first embodiment of the present invention has (when four gas passages are provided).

FIG. 1-4 is a schematic vertical cross-sectional view for explaining the structure of a gas passage near the upper end opening of the plug shown in FIG. 1-2.

FIG. 1-5 is a schematic vertical cross-sectional view for explaining the structure of the gas passage near the lower end opening of the plug shown in FIG. 1-2.

FIG. 1-6 is a formal plan view of a ceramic substrate that the member for a semiconductor manufacturing equipment according to the first embodiment of the present invention has.

FIG. 2-1 is a schematic vertical cross-sectional view of the member for a semiconductor manufacturing equipment according to the second embodiment of the present invention.

FIG. 2-2 is a schematic vertical cross-sectional view through a center axis of a plug that the member for a semiconductor manufacturing equipment according to the second embodiment of the present invention has (where a single gas passage is provided).

FIG. 3 is a schematic vertical cross-sectional view of the member for a semiconductor manufacturing equipment according to the third embodiment of the present invention.

FIG. 4A to 4C show a manufacturing process diagram of a member for a semiconductor manufacturing equipment according to an embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal surface with the upper surface for placing a wafer of the ceramic substrate facing upward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of a Member for Semiconductor Manufacturing Equipment According to First Embodiment

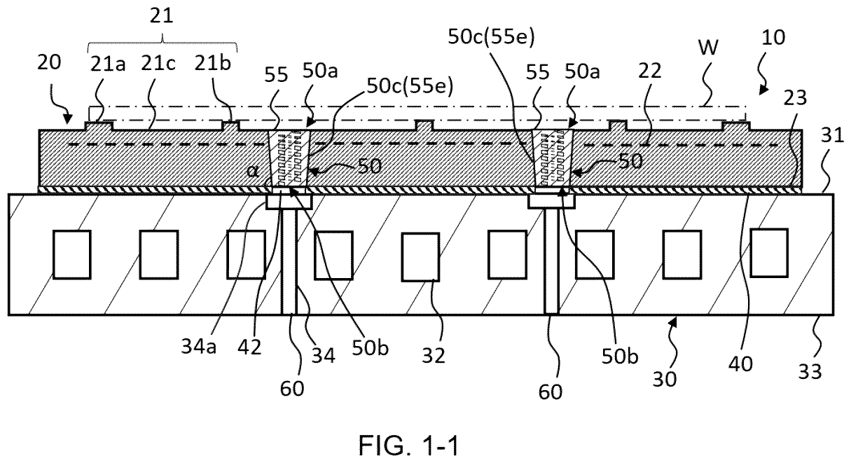

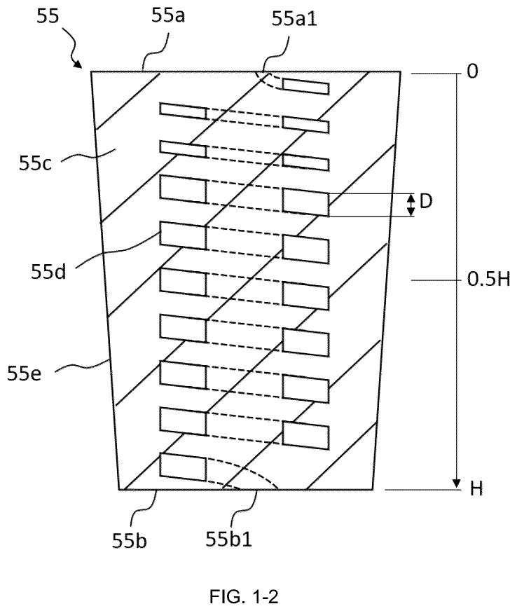

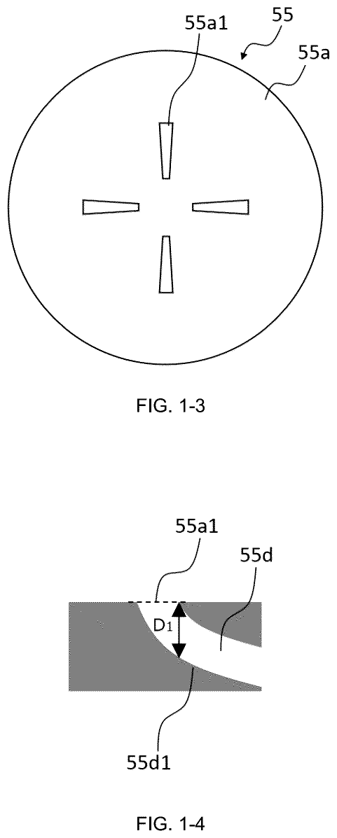

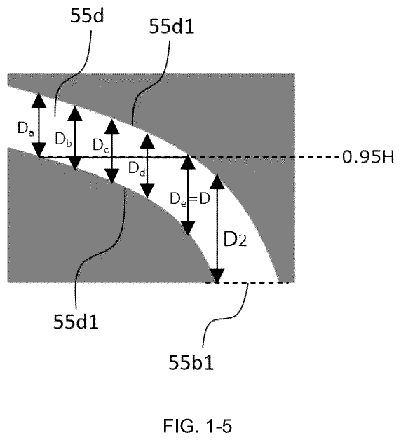

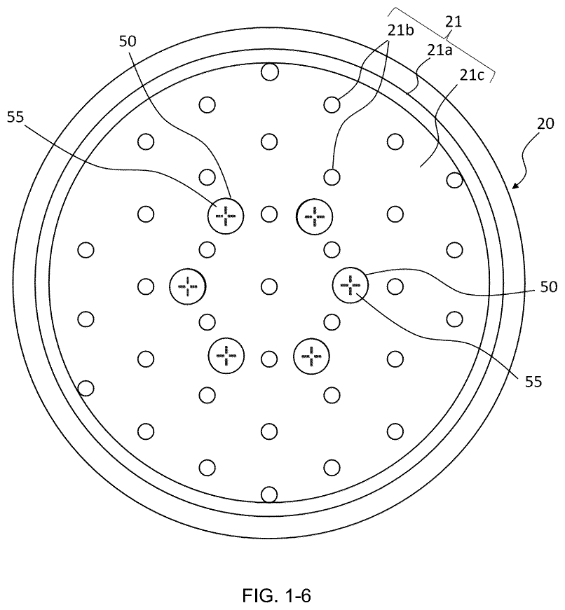

Referring to FIG. 1, a member 10 for a semiconductor manufacturing equipment according to the first embodiment of the present invention comprises a ceramic substrate 20 having an upper surface 21 on which a wafer W is to be placed and a lower surface 23 opposite to the upper surface 21; a plug placement hole 50 that vertically penetrates the ceramic substrate 20; and a plug 55 embedded in the plug placement hole 50. Further, the member 10 for a semiconductor manufacturing equipment comprises a base plate 30 bonded to the lower surface 23 of the ceramic substrate 20 via a bonding layer 40, and a gas supply path 60 that passes through the base plate 30 and the bonding layer 40 and supplies a gas to the plug 55.

### (1-1. Ceramic Substrate)

The upper surface 21 of the ceramic substrate 20 has a wafer placement surface on which the wafer W is to be placed. In addition, an electrode 22 is provided inside the dielectric substrate 20. As shown in FIG. 1-1 and FIG. 1-6, on the upper surface 21 of the ceramic substrate 20, an annular seal band 21a is formed along the outer edge, and a plurality of protrusions 21b are formed on the entire surface inside the seal band 21a. Although the shape of the protrusion 21b is not limited, it can be, for example, a cylinder, a prism, or the like. It is preferable that the seal band 21a and the small protrusions 21b have the same height, and the height is, for example, 5 to 100 μm, and typically 10 to 30 μm. The electrode 22 is a planar electrode used as an electrostatic electrode, and is connected to an external DC power source via a power supply member (not shown). A low-pass filter may be placed in the middle of the power supply member. The power supply member is electrically insulated from the bonding layer 40 and the base plate 30. When a DC voltage is applied to this electrode 22, the wafer W is adsorbed and fixed to the wafer placement surface (specifically, the upper surface of the seal band 21a and the upper surface of the protrusion 21b) by electrostatic attraction force, and when the application of the DC voltage is released, the adsorption and fixation of the wafer W to the wafer placement surface is released. In addition, the portion of the upper surface 21 of the ceramic substrate 20 where the seal band 21a and the projections 21b are not provided is referred to as the reference surface 21c.

As the electrode 22, a heater electrode (resistance heating element) may be incorporated instead of or in addition to the electrostatic electrode. In that case, a heater power source is connected to the heater electrode. One layer of electrode may be provided inside the ceramic substrate 20, or two or more layers which are spaced apart from each other r may be provided inside the ceramic substrate 20.

The ceramic substrate 20 can be, for example, a circular plate (for example, 300 to 400 mm in diameter) made of ceramics such as alumina sintered body or aluminum nitride sintered body. Although the thickness of the ceramic substrate 20 is not limited, from the viewpoint of increasing the fixing strength of the plug 55, it is preferable that the thickness from an upper opening 50a to a lower opening 50b is 1 mm or more. Further, from the viewpoint of reducing heat transfer of the ceramic substrate 20 and reducing manufacturing costs, the thickness is preferably 5 mm or less, more preferably 3 mm or less, and even more preferably 2 mm or less. Therefore, the thickness from the upper opening 50a to the lower opening 50b is preferably 1 to 5 mm, more preferably 1 to 3 mm, and even more preferably 1 to 2 mm. Here, the thickness from the upper opening 50a to the lower opening 50b means the distance from the center of gravity of the upper opening 50a to the center of gravity of the lower opening 50b. The height of the upper opening 50a is equal to the height of the reference surface 21c of the upper surface 21 of the ceramic substrate 20. The height of the lower opening 50b is equal to the height of the lower surface 23 of the ceramic substrate 20.

### (1-2. Plug Arrangement Hole)

The plug-placed hole 50 is a hole which penetrates the ceramic substrate 20 in the vertical direction from the upper opening 50a to the lower opening 50b as shown in FIG. 1-1. The plug placement hole 50 functions as a gas passage from the lower surface 23 of the ceramic substrate 20 to the reference surface 21c of the upper surface 21. A single plug placement hole 50 may be provided, but it is preferable to provide a plurality of it. In FIG. 1-6, it is shown that a plurality of plug placement holes 50 are provided (six herein), in each of which a plug 55 is embedded.

The opening diameter (if the cross section of the plug placement hole is not circular, it means the equivalent circle diameter) of the plug placement hole 50 in the horizontal direction is not limited, but may be within the range of 1 to 5 mm, typically within the range of 3 to 4 mm, at any height position. The diameter of the plug placement hole 50 may be constant or may vary from the lower surface 23 to the upper surface 21 of the ceramic substrate 20. In one embodiment, the diameter of the plug placement hole 50 may decrease from top to bottom, and it may have a tapered inner peripheral surface 50c in which the area of the upper opening 50a is larger than the area of the lower opening 50b. Since the plug placement hole 50 has such a tapered inner peripheral surface 50c, when embedding the plug 55 into the plug placement hole 50, the plug 55 can easily stop at a predetermined height position of the plug placement hole 50. Therefore, it is possible obtain an effect that the plug 55 can be embedded in the plug placement hole 50 with high positioning accuracy. Further, while the plug 55 becomes difficult to come out downward, it becomes relatively easy to come out upward, so that the effect of making it easier to replace the plug 55 can be obtained. Furthermore, since the creepage distance becomes longer, an effect of suppressing discharge can also be obtained. The plug placement hole 50 can have, for example, a truncated conical or truncated pyramid space.

The inclination angle α of the inner peripheral surface 50c of the plug placement hole 50 with respect to the lower opening 50b is preferably 70° or more, and preferably 75° or more, from the viewpoint of increasing the fixing strength of the plug 55, and from the viewpoint of suppressing the volume of the plug 55 from becoming excessively large and securing space for arranging the electrode around it. In addition, it is preferable that the inclination angle α be 87° or less, and more preferable that it is 85° or less, from the viewpoint of improving the positioning accuracy in the height direction of the plug when press-fitting the plug 55 downward into the plug placement hole 50, from the viewpoint of making it easy to replace the plug 55, and from the viewpoint of increasing the creepage distance to prevent discharge. Therefore, the inclination angle α is preferably, for example, 70° to 87°, and more preferably 75° to 85°.

### (1-3. Plug)

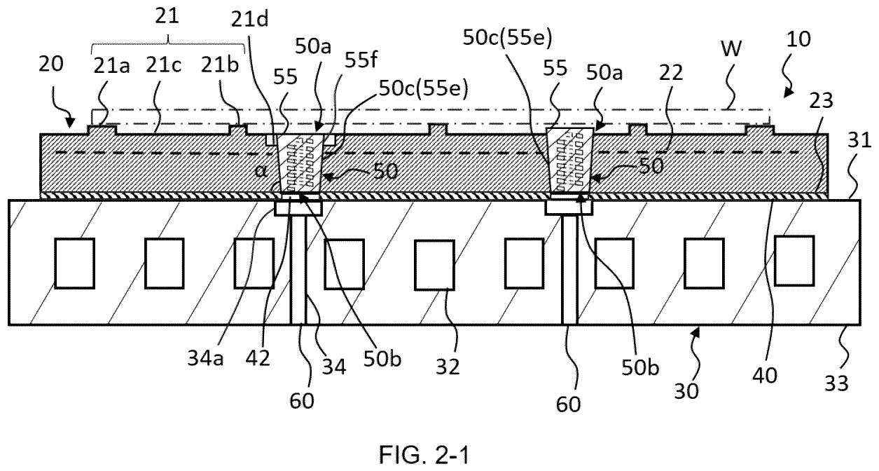

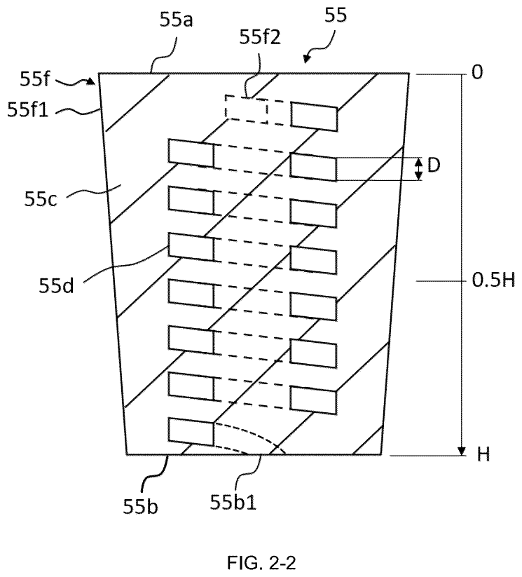

The plug 55 is embedded in the plug placement hole 50. FIG. 1-2 shows a schematic vertical cross-sectional view that passes through the center axis of the plug 55 (when one gas passage is provided). FIG. 1-3 shows a schematic plan view of the plug 55 (when four gas passages are provided). The plug 55 is composed of a dense body 55c and comprises an upper end surface 55a exposed on the side of the upper surface 21 of the ceramic substrate 20, a lower end surface 55b exposed on the side of the lower surface 23 of the ceramic substrate 20, and a gas passage 55d that penetrates the inside of the dense body 55c and extends from an upper end opening 55a1 provided on the upper end surface 55a to a lower end opening 55b1 of the lower end surface 55b.

As used herein, the dense body 55c refers to the portion constituting the plug 55 and having a porosity of 5% or less. The partial porosity of the plug 55 is measured by the following method. First, the ceramic plug 55 is cut such that a cross section passing through the center axis extending in the vertical direction of plug 55 is exposed. Next, in a cross section, the portion for which the porosity is to be measured is observed using a scanning electron microscope (SEM) at a magnification of 3000 times in approximately 2200 μm², and the area ratio of pores confirmed in the portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pore portions to the total area (total area of the solid portions and the pore portions) is determined, and this is taken as the porosity of the portion to be measured.

In the first embodiment, the gas flowing from the lower end opening 55b1 provided on the lower end surface 55b of the plug 55 may flow through the gas passage 55d provided inside the dense body 55c and may flow out from an upper end opening 55a1 provided on the upper end surface 55a of the plug 55. In one plug 55, only one gas passage 55d may be provided, or two or more gas passages 55d may be provided. From the viewpoint of ensuring a gas flow rate, one plug 55 is preferably provided with 1 to 10 gas passages 55d, and more preferably 4 to 10 gas passages 55d. For simplicity, one gas passage 55d is shown in FIG. 1-2. FIG. 1-3 shows the upper end openings 55a1 that serve as the outlets of four gas passages 55d. The gas passage 55d may be constructed of a straight line, a curved line, or a combination of both, but from the viewpoint of suppressing discharge, it is preferable to have a shape such that the length of the passage is longer than the length of the plug 55 in the vertical direction, for example, a curved shape such as a spiral shape or a zigzag shape.

There is no particular restriction on the opening shape of the upper end opening 55a1. For example, the opening shape can be formed by a straight line, a curved line, or a combination of both. Specifically, the opening shape can be rectangular. Among these, in order to secure the opening area and the area of the plug, the opening shape is preferably an elongated rectangular shape.

The gas passage 55d may be hollow, but at least a portion thereof may be porous as long as gas flow is allowed. When at least a portion of the gas passage 55d is porous, the gas flowing from the lower end opening 55b1 of the plug 55 flows through the gas passage 55d formed by a large number of continuous pores, and flows out from the upper end opening 55a1 of the plug 55. The gas that has flowed out is supplied between the wafer W and the ceramic substrate 20. Since the three-dimensional (for example, three-dimensional network) continuous pores that exist within the porous material serve as gas passages, the substantial passage length within the gas passage 55d becomes longer, and an effect that electric discharge is less likely to occur can be obtained, compared to the case where the gas passage 55d is hollow. It is also possible to further form one or more gas passages within the porous gas channel.

Therefore, the gas passage 55d may be hollow or porous. It is preferable that at least a portion of the gas passage 55d is porous. The fact that the gas passage 55d is hollow means that the porosity is 100%. The fact that the gas passage 55d is porous means that the porosity of the gas passage 55d is greater than 5% and less than 100%. When the gas passage 55d is porous, the porosity of the gas passage 55d is preferably large in order to reduce ventilation resistance. Therefore, the porosity of the gas passage 55d is preferably 10% or more, and more preferably 40% or more. On the other hand, the porosity of the gas passage 55d is preferably 50% or less in order to lengthen the passage length of the plug 55 and ensure structural strength. Therefore, the porosity of the gas passage 55d is, for example, preferably 10% or more and 50% or less, and more preferably 40% or more and 50% or less. The porosity of the gas passage 55d is measured, for example, by mercury porosimetry method (JIS R1655: 2003).

FIG. 1-4 schematically illustrates the structure of the gas passage 55d near the upper end opening 55a1 of the plug 55. Further, FIG. 1-5 schematically illustrates the structure of the gas passage 55d near the lower end opening 55b1 of the plug 55. During wafer processing, gas molecules present between the wafer W and the ceramic substrate 20 are ionized, and in some cases the electrons generated thereby accelerate toward the ceramic substrate 20 and collide with the upper surface 21 of the ceramic substrate 20. Since the higher the gas velocity is, the more likely discharge is to occur, it is effective to shorten the distance between the wafer W and the ceramic substrate 20 in order to suppress the gas velocity.

However, when the upper end opening 55a1 of the plug 55 is exposed on the upper surface 21 of the ceramic substrate 20, the electrons flowing from the upper end opening 55a1 are further accelerated before colliding with the surface 55d1 of the gas passage 55d. Therefore, the shorter the distance from the upper end opening 55a1 to the surface 55d1 of the gas passage 55d is, the more the acceleration time until the electrons flowing into the upper end opening 55a1 collide with the surface of the gas passage 55d can be suppressed, which is desirable. On the other hand, from the viewpoint of securing the necessary gas flow rate when supplying gas between the wafer W and the ceramic substrate 20, it is advantageous that the distance from the lower end opening 55b1 of the gas passage 55d to the surface 55d1 of the gas passage 55d is longer.

Therefore, in one embodiment, for at least one gas passage 55d provided on the plug 55, a maximum height D₁ in the vertical direction from the upper end opening 55a1 to the surface 55d1 of the gas passage 55d, and a maximum height D₂ in the vertical direction from the lower end opening 55b1 to the surface of the gas passage 55d satisfies a relationship: D₁<D₂. In cases where the plug 55 comprise a plurality of gas passages 55d, it is preferable that the relationship D₁<D₂ is satisfied for all of the plurality of gas passages 55d.

Regarding the preferred embodiment of the plug 55, such as the maximum height D₁, the maximum height D₂ of the gas passage 55d, and the gas passage height D as described below, In cases where the plug 55 comprise a plurality of gas passages 55d, it is preferable that all of the plurality of gas passages 55d satisfy the conditions related to those preferred embodiments.

For at least one gas passage 55d provided on the plug 55, it is preferable that the relationship D₁/D_{2≤0.9} is satisfied, more preferably the relationship D₁/D_{2≤0.7} is satisfied, and even more preferably the relationship D₁/D_{2≤0.5} is satisfied. On the other hand, from the viewpoint of securing the necessary gas flow rate when supplying gas between the wafer W and the ceramic substrate 20, It is preferable not to make D₁/D₂ excessively small. Accordingly, it is preferable that the relationship 0.1≤D₁/D₂ is satisfied, more preferably the relationship 0.3≤D₁/D₂ is satisfied, and even more preferably the relationship 0.5≤D₁/D₂ is satisfied. Therefore, for example, it is preferable to satisfy the relationship 0.1≤D₁/D_{2≤0.9}. Furthermore, the relationship 0.5≤D₁/D_{2≤0.7} may be satisfied, or the relationship 0.3≤D₁/D_{2≤0.5} may be satisfied.

It is preferable that the height D of the gas passage 55d in the vertical direction increases continuously or stepwise as the gas passage 55d proceeds downward.

The maximum height D₁ in the vertical direction from the upper end opening 55a1 to the surface 55d1 of the gas passage 55d means, as shown in FIG. 1-4, the length of the longest straight line until it comes into contact with the surface 55d1 of the gas passage 55d, among the straight lines that can extend downward from the upper end opening 55a1 toward the surface 55d1 of the gas passage 55d. Similarly, the maximum height D₂ in the vertical direction from the lower end opening 55b1 to the surface 55d1 of the gas passage 55d means, as shown in FIG. 1-5, the length of the longest straight line until it comes into contact with the surface 55d1 of the gas passage 55d, among the straight lines that can extend upward from the lower end opening 55b1 toward the surface 55d1 of the gas passage 55d.

The smaller the maximum height D₁ is, the more effective it is to suppress discharge. Also, if the maximum height D₁ is set with a margin on the safe side, the risk of discharge can be suppressed even when the distance in the height direction from the back surface of the wafer W to the surface 55d1 of the gas passage 55d exposed to the upper end opening 55a1 becomes longer due to some reason. Examples of “some reason” may be as follow: (a) chipping occurs near the upper end opening 55a1 of the plug 55 and the gas passage 55d is chipped; (b) when the plug 55 is embedded in the plug placement hole 50, the plug 55 sinks below a predetermined position; (c) the machining accuracy of the plug 55 itself is low; or the like. On the other hand, from the viewpoint of ensuring the necessary gas flow rate when supplying gas between the wafer W and the ceramic substrate 20, it is desirable that the maximum height D₁ is large. Therefore, considering the balance between the two, the maximum height D₁ is preferably 10 to 300 μm, more preferably 40 to 100 μm, and even more preferably 60 to 100 μm.

The maximum height D₂ is desirably large from the viewpoint of securing the gas flow rate necessary when supplying gas between the wafer W and the ceramic substrate 20. On the other hand, from the viewpoint of ensuring the passage length and the plug strength, it is preferable not to make it excessively large. Therefore, considering the balance between these two factors, the maximum height D₂ is preferably 50 to 500 μm, more preferably 50 to 300 μm, and even more preferably 100 to 200 μm.

From the viewpoint of securing the necessary gas flow rate when supplying gas between the wafer W and the ceramic substrate 20, it is preferable that the height D of the gas passage 55d in the vertical direction is large, except for the vicinity of the upper end surface 55a of the plug 55, where the height D of the gas passage 55d in the vertical direction needs to be set small in order to suppress the risk of electrical discharge. Therefore, when taking a coordinate axis in the vertical direction (see FIG. 1-2), and assuming the coordinate value of the upper end surface 55a of the plug 55 is 0, and the coordinate value of the lower end surface 55b is H, the height D of the gas passage 55d in the vertical direction preferably satisfies a relationship D≥1.5 D₁, more preferably satisfies a relationship D≥2D₁, at least within the range of coordinate value from 0.5×H to 1.0×H, and more preferably the range of coordinate value from 0.1×H to 1.0×H. However, from the viewpoint of reducing the risk of discharge by ensuring the passage length and from the viewpoint of ensuring plug strength, it is preferable not to make the height D of the gas passage 55d in the vertical direction excessively large. Specifically, the height D of the gas passage 55d in the vertical direction preferably satisfies a relationship 30 D₁, more preferably satisfies a relationship 20 D₁≥D, and even more preferably satisfies a relationship 10 D₁≥D, at least within the range of coordinate value from 0.5×H to 1.0×H, and more preferably the range of coordinate value from 0.1×H to 1.0×H. Therefore, for example, the height D of the gas passage 55d in the vertical direction preferably satisfies a relationship 30 D₁≥D≥1.5 D₁, more preferably satisfies a relationship 20 D₁≥D≥2D₁, and even more preferably satisfies a relationship 10 D₁≥D≥2D₁, at least within the range of coordinate value from 0.5×H to 1.0×H, and more preferably the range of coordinate value from 0.1×H to 1.0×H.

In order to suppress the risk of electrical discharge, in addition to the maximum height D₁ in the vertical direction from the upper end opening 55a1 of the plug 55 to the surface 55d1 of the gas passage 55d, in the vicinity of the upper end surface 55a of the plug 55, it is preferable to set the height D of the gas passage 55d in the vertical direction small on the condition that it does not become less than the maximum height D₁. Specifically, the height D of the gas passage 55d in the vertical direction preferably satisfies a relationship D₁≤D<1.5 D₁ at least within the range of coordinate value from 0 to less than 0.1×H.

The height D of the gas passage 55d in the vertical direction at a specific coordinate value is the length of the longest straight line among straight lines extending in the vertical direction connecting the opposing surfaces 55d1 of the gas passage 55d and that can intersect or touch the horizontal plane passing the specific coordinate value. In order to explain this, the height D of the gas passage 55d at a coordinate value of 0.95H is schematically shown in FIG. 1-5. As can be understood from FIG. 1-5, there are many straight lines that extend in the vertical direction connecting the opposing surfaces 55d1 of the gas passage 55d and that can intersect or touch a horizontal plane (horizontal line in the figure) passing the coordinate value 0.95H. Here, for simplicity, five straight lines are drawn that satisfy the conditions. The lengths of the five straight lines are Dₐ, D_{b}, D_{c}, D_{d}, and Dₑ, respectively. Among these, the length of the longest straight line is Dₑ. Therefore, the height D of the gas passage 55d at the coordinate value 0.95H is Dₑ. The height D of the gas passage 55d in the vertical direction can be measured, for example, by obtaining three-dimensional shape information of the gas passage 55d using X-ray CT. In addition, regardless of the above definition, the height D of the gas passage 55d at the coordinate value 0 is set to D₁, and the height D of the gas passage 55d at the coordinate value H is set to D₂.

In order to suppress occurrence of chipping near the upper end opening 55a1 of the plug 55, it is desirable that the plug 55 has a large fracture toughness value (KIC). Specifically, it is preferable that the fracture toughness value (KIC) of the portion of the plug 55 composed of the dense body 55c is larger than the fracture toughness value (KIC) of the ceramic substrate 20. Since the processing conditions for components for semiconductor manufacturing equipment are often set based on the ceramic substrate 20, when the fracture toughness value (KIC) of the portion of the plug 55 composed of the dense body 55c is larger than the fracture toughness value (KIC) of the ceramic substrate 20, the risk of chipping occurring in the plug 55 is reduced.

The fracture toughness value (KIC) of the portion of the plug 55 composed of the dense body 55c is preferably 2 MPa·m^{1/2} or more, more preferably 3 MPa·m^{1/2} or more, and even more preferably 4 MPa·m^{1/2} or more. Although no particular upper limit is set for the fracture toughness value (KIC) of the portion of the plug 55 composed of the dense body 55c, from the viewpoint of ease of manufacture, it is preferably 13 MPa·m^{1/2} or less, more preferably 12 MPa·m^{1/2} or less, and even more preferably 11 MPa·m^{1/2} or less. Therefore, the fracture toughness value (KIC) of the portion of the plug 55 composed of the dense body 55c is preferably 2 to 13 MPa·m^{1/2}, more preferably 3 to 12 MPa·m^{1/2}, and even more preferably 4 to 11 MPa·m^{1/2}.

The fracture toughness value (KIC) of the portion of the plug 55 composed of the dense body 55c and the ceramic substrate 20 is measured in accordance with the Single Edge Precracked Beam method (SEPB method) specified in JIS R1607: 2015.

As the material constituting the plug 55, electrically insulating ceramics can be used, and for example, it may contain one or more selected from aluminum oxide, aluminum nitride, and silicon dioxide. It can also be composed of only one or two selected from aluminum oxide, aluminum nitride, and silicon dioxide, excluding impurities. Quartz is preferable as silicon dioxide. In particular, in order to control the fracture toughness value (KIC) of the portion of the plug 55 composed of the dense body 55c within the above range, it is preferable that the portion of the plug 55 composed of the dense body 55c be made of a ceramic material such as alumina (aluminum oxide) having high fracture toughness.

Further, in order to maintain the fixing strength of the plug 55 embedded in the plug placement hole 50, it is preferable that the difference in thermal expansion coefficient between the plug 55 and the ceramic substrate 20 is small. Therefore, the material constituting the plug 55 and the material constituting the ceramic substrate 20 preferably both contain at least one selected from aluminum oxide and aluminum nitride, and it is more preferable that the material compositions are the same.

The height position of the upper end surface 55a of the plug 55 is not limited. Therefore, the height position of the upper end surface 55a of the plug 55 may be the same height as the reference surface 21c of the ceramic substrate 20, or may be at a different height. When making the upper end surface 55a of the plug 55 lower than the reference surface 21c, in order to suppress the occurrence of discharge, it is preferable to arrange it at a lower position within the range of 0.5 mm or less (preferably 0.2 mm or less, and more preferably 0.1 mm or less). When the upper end surface 55a of the plug 55 is made higher than the reference surface 21c, there is no particular restriction as long as the upper end surface 55a of the plug 55 is made lower than the upper surface of the protrusion 21b and the outflow of gas from the plug 55 is not inhibited.

There is no particular restriction on the height position of the lower end surface 55b of the plug 55. Therefore, the height position of the lower end surface 55b of the plug 55 may be the same height as the lower surface 23 of the ceramic substrate 20, or may be at a different height. For example, the lower end surface 55b of the plug 55 may protrude below the lower surface 23 of the ceramic substrate 20, or the lower end surface 55b of the plug 55 may be provided above the lower surface 23 of the ceramic substrate 20.

The outer peripheral surface 55e of the plug 55 and the inner peripheral surface 50c of the plug placement hole 50 may be bonded together with an adhesive, but it is preferable that they fit directly together without using an adhesive. If the two are directly fitted, no gap will be created between the plug 55 and the plug placement hole 50 caused by deterioration due to corrosion or erosion of the adhesive. Therefore, there is an advantage that discharge and falling off of the plug 55 due to deterioration of the adhesive can be suppressed.

Furthermore, as shown in FIG. 1-1, when observing a vertical cross section obtained by cutting the ceramic substrate 20 in the thickness direction, from the viewpoint of improving the fixing strength of the plug 55, it is preferable that the inner peripheral surface 50c of the plug placement hole 50 be in contact with the outer peripheral surface 55e of the plug 55 in a parallel positional relationship. In other words, the outer peripheral surface 55e of the plug 55 has the same inclination angle as the inner peripheral surface 50c of the plug placement hole 50. Therefore, in a preferred embodiment, the plug 55 has the same outer shape as the plug placement hole 50 (for example, a truncated cone shape or a truncated pyramid shape). Thereby, the area where the inner peripheral surface 50c of the plug 55 contacts the outer peripheral surface 55e of the plug 55 can be increased, and high fixing strength can be obtained.

An example of a direct fitting method is a method of embedding the plug 55 by press-fitting it into the plug placement hole 50. In this case, in order to obtain the desired fixation strength, it is preferable that the cross-sectional diameter in the horizontal direction at any height position of the plug 55 before press-fitting is made slightly larger (for example, by about 5 to 20 μm in equivalent circle diameter) than the horizontal cross-sectional diameter of the plug placement hole 50 located at the same height position. Further, as a direct fitting method, there is also a method in which a male threaded portion provided on the outer peripheral surface 55a of the plug 55 is screwed into a female threaded portion provided on the inner peripheral surface 50c of the plug placement hole 50.

As a method for manufacturing the plug 55 having such a dense body 55c and a gas passage 55d penetrating the inside thereof, mention may be made to a method of firing a molded body formed using an additive manufacturing technology such as a 3D printer, for example. Further, the plug 55 may be formed by mold casting. Details of mold casting are disclosed in, for example, Japanese Patent No. 5458050. In mold casting, a ceramic slurry containing ceramic powder, a solvent, a dispersant, and a gelling agent is injected into a molding space of a mold, and a molded body is formed in the mold by causing a chemical reaction with the gelling agent to gel the ceramic slurry. In the mold casting, a molded body may also be formed in a forming mold using an outer mold and a core (a mold having the same shape as the gas passage 55d) made of a material with a low melting point such as wax, and thereafter, a molded article may be produced by heating the forming mold to a temperature equal to or higher than the melting point of the mold to melt and remove the forming mold or to eliminate it by combustion. Next, a porous raw material is placed in the cavity corresponding to the gas passage 55d in the obtained molded body. Specifically, for example, a raw material, in which pore-forming materials such as resin and wax have been added to aggregates such as ceramic powder, is filled into a cavity corresponding to the gas passage 55d of a molded body. A solvent can be added as necessary to make it into a slurry or paste. Finally, the entire material is fired. By this firing, the pore-forming material in the porous raw material disappears so that a porous portion is formed, and a plug 55 in which a dense body and the porous portion are integrated is obtained.

The porosity of the plugs 55 can be controlled, for example, by adjusting the content of the pore-forming material in the raw material composition before producing by firing the ceramics which they are made of. For example, in order to make the plug 55 denser, the amount of pore-forming material may be reduced or it may not be used.

### (1-4. Base Plate)

The base plate 30 may be a circular plate (having a diameter equal to or larger than that of the ceramic substrate 20) with good electrical conductivity and thermal conductivity, for example. Referring to FIG. 1-1, inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port. The base plate 30 is connected to a radio frequency (RF) power source and can also be used as an RF electrode.

Examples of the material constituting the base plate 30 include metal materials and composite materials of metal and ceramics. Examples of the metal material include Al, Ti, Mo, W, and alloys thereof. Examples of composite materials of metal and ceramics include metal matrix composites (MMC) and ceramic matrix composites (CMC). Specific examples of such composite materials include materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the ceramic substrate 20. For example, when the ceramic substrate 20 is made of alumina, the base plate is preferably made of SiSiCTi or AlSiC.

### (1-5. Bonding Layer)

As shown in FIG. 1-1, the upper surface 31 of the base plate 30 is bonded to the lower surface 23 of the ceramic substrate 20 via a bonding layer 40. The bonding layer 40 is formed by, for example, TCB (thermal compression bonding). TCB is a known method in which a metal bonding material is sandwiched between two members to be bonded, and the two members are pressure bonded while being heated to a temperature below the solidus temperature of the metal bonding material. The bonding layer 40 can be composed of a metal bonding layer using, for example, an Al—Mg-based bonding material or an Al—Si—Mg-based bonding material. The bonding layer 40 may be a layer formed of solder or a metal brazing material. Furthermore, the bonding layer 40 may be composed of a resin adhesive layer instead of the metal bonding layer. Examples of the material for the resin adhesive layer include silicone resin-based adhesives, epoxy resin-based adhesives, and acrylic resin-based adhesives. In order to improve the uniformity of the thickness of the resin adhesive layer, a spacer (not shown) may be placed between the upper surface 31 of the base plate 30 and the lower surface 23 of the ceramic substrate 20.

The bonding layer 40 has a through hole 42. The through hole 42 is provided at a position facing a large diameter portion 34a of a gas hole 34. The through hole 42 may be provided coaxially with the large diameter portion 34a, and the diameter of the through hole 42 may be made to match the diameter of the large diameter portion 34a. As used herein, “match” includes not only a complete match but also a substantially match (for example, within a tolerance range) (the same applies hereinafter). A plurality of through-holes 42 may be provided for one plug 55, and in this case, it is preferable that a plurality of through-holes 42 be provided point-symmetrically with respect to the central axis of the plug 55 extending in the vertical direction. The size of each through hole 42 can be made smaller by providing a plurality of through holes 42 rather than using one large through hole 42. Thereby, the risk of electric discharge can be reduced. Further, by providing a plurality of through holes 42, a necessary gas flow rate can be ensured.

### (1-6. Gas Supply Path)

Referring to FIG. 1-1, the gas supply path 60 for supplying gas to the plug 55 through the base plate 30 and the bonding layer 40 has, for example, a through hole 42 that vertically penetrates the bonding layer 40 and a gas hole 34 that communicates with the through hole 42 and penetrates the base plate 30 from the upper surface 31 to the lower surface 33. The upper surface 31 of the base plate 30 may further comprise a large diameter portion 34a provided at a position facing the through hole 42. By having the through hole 42 and furthermore the large diameter portion 34a, when placing the plug 55 in the plug placement hole 50, even if there is a manufacturing error in the plug placement hole 50 and/or the plug 55, such a manufacturing error can be absorbed because a space is created that allows the plug 55 to enter.

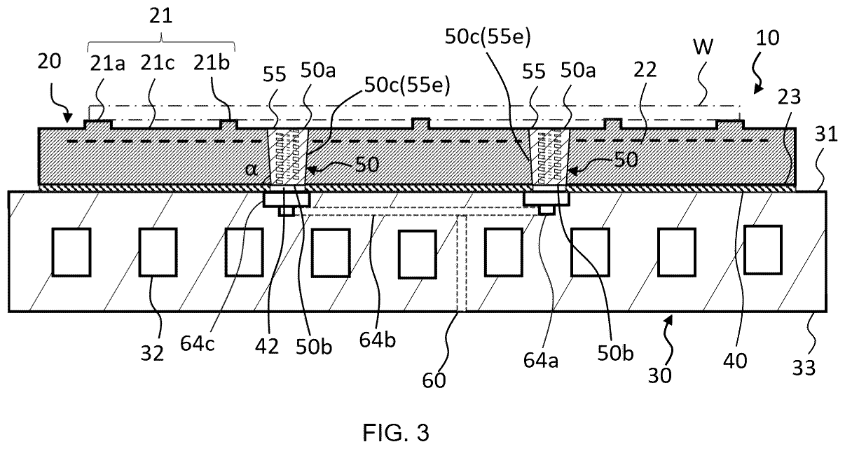

There are no particular restrictions on the configuration of the gas supply path 60. For example, like a member 10 for a semiconductor manufacturing equipment according to another embodiment of the present invention shown in FIG. 3, the base plate 30 may be provided with one or more ring portions 64a having a passage extending concentrically with the base plate 30 in a plan view, one or more gas introduction portions 64b that supply the gas introduced from the lower surface 33 of the base plate 30 to the ring portions 64a, and a distribution portion 64c that distributes gas from the ring portions 64a to each plug 55. In the present embodiment, the upper end of the distribution portion 64c communicates with the through hole 42 of the bonding layer 40. In FIG. 3, the same components as those in the embodiment shown in FIG. 1-1 are given the same reference numerals. The number of gas introduction portions 64b may be smaller than the number of distribution portions 64c, and may be one, for example. In this way, the number of gas pipes connected to the base plate 30 can be made smaller than the number of plugs 55. Other auxiliary passages not shown may also be provided.

### (1-7. Others)

A lift pin hole may be provided that penetrates the member 10 for semiconductor manufacturing equipment. The lift pin hole is a hole through which a lift pin for moving the wafer W up and down with respect to the upper surface 21 of the ceramic substrate 20 is inserted. Lift pin holes are provided at three locations when the wafer W is supported by, for example, three lift pins.

### 2. Configuration of a Member for Semiconductor Manufacturing Equipment According to Second Embodiment

Referring to FIG. 2-1, a member 10 for a semiconductor manufacturing equipment according to the second embodiment of the present invention comprises a ceramic substrate 20 having an upper surface 21 on which a wafer W is to be placed and a lower surface 23 opposite to the upper surface 21; a plug placement hole 50 that vertically penetrates the ceramic substrate 20; and a plug 55 embedded in the plug placement hole 50. Further, the member 10 for a semiconductor manufacturing equipment comprises a base plate 30 bonded to the lower surface 23 of the ceramic substrate 20 via a bonding layer 40, and a gas supply path 60 that passes through the base plate 30 and the bonding layer 40 and supplies a gas to the plug 55.

A schematic vertical cross-sectional view of the plug 55 is shown in FIG. 2-2. The plug 55 is composed of a dense body 55c and comprises an upper end portion 55f having an upper end surface 55a exposed on the side of the upper surface 21 of the ceramic substrate 20, a lower end surface 55b exposed on the side of the lower surface 23 of the ceramic substrate 20, and a gas passage 55d that penetrates the inside of the dense body 55c and extends from the side surface opening 55f2 provided on the side surface 55f1 of the upper end portion 55f to the lower end opening 55b1 of the lower end surface 55b. Therefore, the plug 55 does not have an opening for the gas passage 55d on the upper end surface 55a. Thereby, there is no risk that accelerated electrons will flow into the upper end surface 55a and collide with the gas passage 55d during wafer processing, so that the risk of electric discharge can be suppressed.

As mentioned above, as used herein, the dense body 55c refers to a portion of the plug 55 that has a porosity of 5% or less. The partial porosity of the plug 55 is measured by the method described above.

In the second embodiment, the gas flowing from the lower end opening 55b1 provided on the lower end surface 55b of the plug 55 may flow through the gas passage 55d provided inside the dense body 55c, and may flow out from the side surface opening 55f2 provided on the side surface 55f1 of the upper end portion 55f of the plug 55. In one plug 55, only one gas passage 55d may be provided, or two or more gas passages 55d may be provided. The gas passage 55d may be constructed of a straight line, a curved line, or a combination of both, but from the viewpoint of suppressing discharge, it is preferable to have a shape in which the length of the passage is longer than the length of the plug 55 in the vertical direction, for example, a curved shape such as a spiral shape or a zigzag shape.

When the plug 55 has a plurality of gas passages 55d, it is preferable that each of the plurality of gas passages 55d extend from the side surface opening 55f2 provided on the side surface 55f1 of the upper end portion 55f, through the inside of the dense body 55c, to the lower end opening 55b1 provided on the lower end surface 55b.

When taking the coordinate axis in the vertical direction (see FIG. 2-2), and assuming the coordinate value at the upper end surface 55a of the plug 55 is 0, and the coordinate value at the lower end surface 55b is H, the upper end portion 55f of the plug 55 refers to a range of coordinate value from 0 to 0.1×H. In order to ensure the passage length and to suppress the height from the wafer placement surface to the side surface opening 55f2 and suppress electric discharge, the side surface opening 55f2 at the upper end portion 55f of the plug 55 is preferably provided within a range of coordinate value from 0.01×H to 0.06×H, more preferably provided within a range of coordinate value from 0.01×H to 0.05×H, and even more preferably provided within a range of coordinate value of 0.01×H to 0.04×H.

The gas passage 55d may be hollow, but at least a portion thereof may be porous as long as gas flow is allowed. When at least a portion of the gas passage 55d is porous, the gas flowing in from the lower end opening 55b1 of the plug 55 flows through the gas passage 55d formed by a large number of continuous pores, and flows out from the side surface opening 55f2 at the upper end portion 55f of the plug 55. The gas that has flowed out is supplied between the wafer W and the ceramic substrate 20. Since the three-dimensional (for example, three-dimensional network) continuous pores that exist within the porous material serve as gas passages, the substantial passage length within the gas passage 55d becomes longer, and an effect that electric discharge is less likely to occur can be obtained, compared to the case where the gas passage 55d is hollow. It is also possible to further form one or more gas passages within the porous gas channel.

Therefore, the gas passage 55d may be hollow or porous. It is preferable that at least a portion of the gas passage 55d is porous. The fact that the gas passage 55d is hollow means that the porosity is 100%. The fact that the gas passage 55d is porous means that the porosity of the gas passage 55d is greater than 5% and less than 100%. When the gas passage 55d is porous, the porosity of the gas passage 55d is preferably large in order to reduce ventilation resistance. Therefore, the porosity of the gas passage 55d is preferably 10% or more, and more preferably 40% or more. On the other hand, the porosity of the gas passage 55d is preferably 50% or less in order to lengthen the passage length of the plug 55 and ensure structural strength. Therefore, the porosity of the gas passage 55d is, for example, preferably 10% or more and 50% or less, and more preferably 40% or more and 50% or less. The porosity of the gas passage 55d is measured, for example, by mercury porosimetry method (JIS R1655: 2003).

In the second embodiment, the gas flows out from the side surface opening 55f2 provided on the side surface 55f1 of the upper end portion 55f of the plug 55. Therefore, it is necessary to ensure a gas passage such that the gas flowing out from the side surface opening 55f2 is supplied between the wafer W and the ceramic substrate 20. Therefore, in one embodiment, a recess 21d is formed in the upper surface 21 of the ceramic substrate 20 on which a wafer W is to be placed, and the upper end portion 55f of the plug 55 protrudes from the bottom surface of the recess 21d such that the side surface opening 55f2 is exposed (see the plug 55 on the left side of FIG. 2-1). The recess 21d can be formed below the reference surface 21c. In this case, even if accelerated electrons collide with the recess 21d, the risk of electrical discharge is low because the ceramic is an insulator and does not have a conductive path. In another embodiment, the upper end portion 55f of the plug 55 protrudes from the reference surface 21c of the ceramic substrate 20 such that the side surface opening 55f2 is exposed (see the plug 55 on the right side of FIG. 2-1).

The height position of the upper end surface 55a of the plug 55 is not limited. Therefore, the height position of the upper end surface 55a of the plug 55 may be the same height as the reference surface 21c of the ceramic substrate 20, or may be at a different height. When making the upper end surface 55a of the plug 55 lower than the reference surface 21c, in order to suppress the occurrence of discharge, it is preferable to arrange it at a lower position within the range of 0.5 mm or less (preferably 0.2 mm or less, and more preferably 0.1 mm or less). When the upper end surface 55a of the plug 55 is made higher than the reference surface 21c, there is no particular restriction as long as the upper end surface 55a of the plug 55 is made lower than the upper surface of the protrusion 21b and the outflow of gas from the plug 55 is not inhibited.

There is no particular restriction on the height position of the lower end surface 55b of the plug 55. Therefore, the height position of the lower end surface 55b of the plug 55 may be the same height as the lower surface 23 of the ceramic substrate 20, or may be at a different height. For example, the lower end surface 55b of the plug 55 may protrude below the lower surface 23 of the ceramic substrate 20, or the lower end surface 55b of the plug 55 may be provided above the lower surface 23 of the ceramic substrate 20.

In the second embodiment, there is no restriction regarding the height D of the gas passage in the vertical direction, as described in the first embodiment. Therefore, the height D of the gas passage 55d in the vertical direction may be constant or may be changed midway. However, from the viewpoint of ensuring a necessary gas flow rate when supplying gas between the wafer W and the ceramic substrate 20, the height D of the gas passage in the vertical direction 55d is preferably large. Specifically, the height D of the gas passage 55d in the vertical direction is preferably 10 μm or more, more preferably 50 μm or more, and even more preferably 100 μm or more, over the entire length of the gas passage 55d. On the other hand, from the viewpoint of reducing the risk of discharge by ensuring the passage length and ensuring the strength of the plug, the height D of the gas passage 55d in the vertical direction is preferably 300 μm or less, more preferably 200 μm or less, over the entire length of the gas passage 55d. The height D of the gas passage 55d in the vertical direction is, for example, preferably 10 to 300 μm, more preferably 50 to 200 μm, and even more preferably 100 to 200 μm, over the entire length of the gas passage 55d. When a coordinate axis is taken in the vertical direction, the definition of the height D of the gas passage 55d in the vertical direction at a specific coordinate value is as described above.

From the viewpoint of suppressing the growth of microscopic cracks that may occur in the plug, it is desirable that the plug 55 has a large fracture toughness value (KIC). Specifically, it is preferable that the fracture toughness value (KIC) of the portion of the plug 55 composed of the dense body 55c is larger than the fracture toughness value (KIC) of the ceramic substrate 20. Since the processing conditions for components for semiconductor manufacturing equipment are often set based on the ceramic substrate 20, when the fracture toughness value (KIC) of the portion of the plug 55 composed of the dense body 55c is larger than the fracture toughness value (KIC) of the ceramic substrate 20, the risk of chipping occurring in the plug 55 is reduced.

The fracture toughness value (KIC) of the portion of the plug 55 composed of the dense body 55c is preferably 2 MPa·m^{1/2} or more, more preferably 3 MPa·m^{1/2} or more, and even more preferably 4 MPa·m^{1/2} or more. Although no particular upper limit is set for the fracture toughness value (KIC) of the portion of the plug 55 composed of the dense body 55c, from the viewpoint of ease of manufacture, it is preferably 13 MPa·m^{1/2} or less, more preferably 12 MPa·m^{1/2} or less, and even more preferably 11 MPa·m^{1/2} or less. Therefore, the fracture toughness value (KIC) of the portion of the plug 55 composed of the dense body 55c is preferably 2 to 13 MPa·m^{1/2}, more preferably 3 to 12 MPa·m^{1/2}, and even more preferably 4 to 11 MPa·m^{1/2}.

The fracture toughness value (KIC) of the portion of the plug 55 composed of the dense body 55c and the ceramic substrate 20 is measured in accordance with the Single Edge Precracked Beam method (SEPB method) specified in JIS R1607: 2015.

As the material constituting the plug 55, electrically insulating ceramics can be used, and for example, it may contain one or more selected from aluminum oxide, aluminum nitride, and silicon dioxide. It can also be composed of only one or two selected from aluminum oxide, aluminum nitride, and silicon dioxide, excluding impurities. Quartz is preferable as silicon dioxide. In particular, in order to control the fracture toughness value (KIC) of the portion of the plug 55 composed of the dense body 55c within the above range, it is preferable that the portion of the plug 55 composed of the dense body 55c be made of a ceramic material such as alumina (aluminum oxide) having high fracture toughness.

Further, in order to maintain the fixing strength of the plug 55 embedded in the plug placement hole 50, it is preferable that the difference in thermal expansion coefficient between the plug 55 and the ceramic substrate 20 is small. Therefore, the material constituting the plug 55 and the material constituting the ceramic substrate 20 preferably both contain at least one selected from aluminum oxide and aluminum nitride, and it is more preferable that the material compositions are the same.

The outer peripheral surface 55e of the plug 55 and the inner peripheral surface 50c of the plug placement hole 50 may be bonded together with an adhesive, but it is preferable that they fit directly together without using an adhesive. By directly fitting the two, no gap is created between the plug 55 and the plug placement hole 50 due to deterioration as a result of corrosion or erosion of the adhesive. Therefore, there is an advantage that discharge and falling off of the plug 55 due to deterioration of the adhesive can be suppressed.

Furthermore, as shown in FIG. 2-1, when observing a vertical cross section obtained by cutting the ceramic substrate 20 in the thickness direction, from the viewpoint of improving the fixing strength of the plug 55, it is preferable that the inner peripheral surface 50c of the plug placement hole 50 be in contact with the outer peripheral surface 55e of the plug 55 in a parallel positional relationship. In other words, the outer peripheral surface 55e of the plug 55 has the same inclination angle as the inner peripheral surface 50c of the plug placement hole 50. Therefore, in a preferred embodiment, the plug 55 has the same outer shape as the plug placement hole 50 (for example, a truncated cone shape or a truncated pyramid shape). Thereby, the area where the inner peripheral surface 50c of the plug 55 contacts the outer peripheral surface 55e of the plug 55 can be increased, and high fixing strength can be obtained.

An example of a direct fitting method is a method of embedding the plug 55 by press-fitting it into the plug placement hole 50. In this case, in order to obtain the desired fixation strength, it is preferable that the cross-sectional diameter in the horizontal direction at any height position of the plug 55 before press-fitting is made slightly larger (for example, by about 5 to 20 μm in equivalent circle diameter) than the horizontal cross-sectional diameter of the plug placement hole 50 located at the same height position. Further, as a direct fitting method, there is also a method in which a male threaded portion provided on the outer peripheral surface 55a of the plug 55 is screwed into a female threaded portion provided on the inner peripheral surface 50c of the plug placement hole 50.

As a method for manufacturing the plug 55 having such a dense body and a gas passage penetrating the inside thereof, mention may be made to a method of firing a molded body formed using an additive manufacturing technology such as a 3D printer, for example. Alternatively, it may be formed by mold casting. The details of mold casting are as described above.

The porosity of the plug can be controlled, for example, by adjusting the content of the pore-forming material in the raw material composition before producing the ceramic material that constitutes the plug by firing. For example, in order to make the plug denser, the amount of pore-forming material may be reduced or it may not be used.

Other configurations of the member 10 for a semiconductor manufacturing equipment according to the second embodiment are the same as those described for the member 10 for a semiconductor manufacturing equipment according to the first embodiment, so duplicate description will be omitted.

### <3. How to Use a Member for Semiconductor Manufacturing Equipment>

Next, a method of using the member 10 for a semiconductor manufacturing equipment configured in this way will be exemplified. First, a wafer W is placed on the upper surface 21 of the ceramic substrate 20 with the member 10 for a semiconductor manufacturing equipment installed in a chamber (not shown). Then, the pressure inside the chamber is reduced with a vacuum pump and adjusted to the desired degree of vacuum, and a voltage is applied to the electrodes 22 of the ceramic substrate 20 to generate electrostatic adsorption force, and the wafer W is adsorbed and fixed to the wafer placement surface (specifically, the upper surface of the seal band 21a or the upper surface of the protrusion 21b).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member 10 for a semiconductor manufacturing equipment to generate plasma. The surface of the wafer W is processed by the generated plasma. A refrigerant circulates in the refrigerant passage 32 of the base plate 30. The backside gas for cooling or the like is introduced into the gas supply path 60 from a gas cylinder (not shown) between the wafer W and the ceramic substrate 20 for the purpose of increasing the heat transfer efficiency and promoting cooling. A thermally conductive gas (for example, He gas) can be used as the backside gas. The backside gas is supplied to the plurality of the plug placement holes 50 through the gas supply path 60, and is supplied and sealed in the space between the back surface of the wafer W and the reference surface 21c of the wafer placement surface. The presence of this backside gas allows efficient heat conduction between the wafer W and the ceramic substrate 20.

Further, by providing the plug 55 in the plug placement hole 50, electric discharge within the plug placement hole 50 can be suppressed. If there is no plug 55, electrons generated as gas molecules are ionized by the application of RF voltage are accelerated and collide with other gas molecules, causing glow discharge and eventually arc discharge. However, when the plug 55 is present, the electrons hit the plug 55 before colliding with the other gas molecules, so that discharge is suppressed.

### <4. Method for Manufacturing a Member for Semiconductor Manufacturing Equipment>

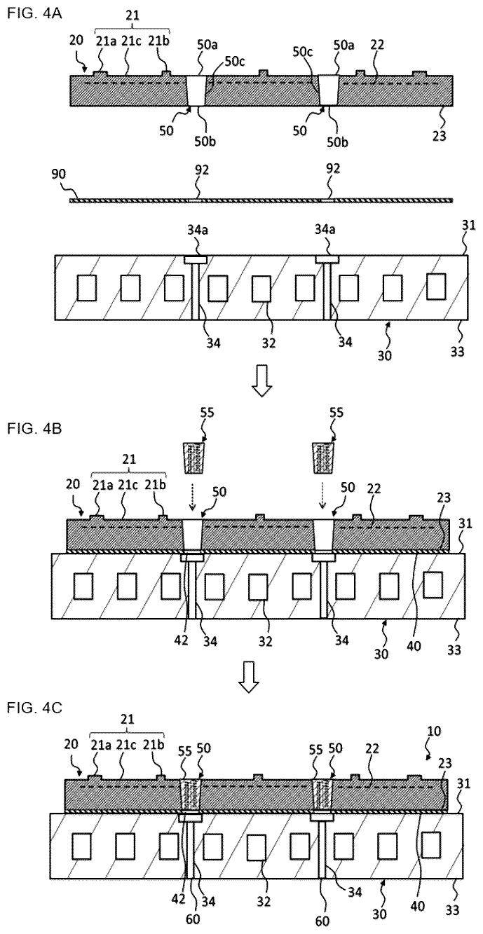

Next, a method for manufacturing the member 10 for a semiconductor manufacturing equipment will be exemplarily described based on FIG. 4. First, a ceramic substrate 20, a base plate 30, and a metal bonding material 90 are prepared (FIG. 4A). The ceramic substrate 20 can be prepared by the following procedure. A disk-shaped sintered ceramic plate, which is the precursor of the ceramic substrate 20, is prepared by hot-press firing a molded body of ceramic powder. The molded body may be prepared by laminating a plurality of tape molded bodies, or may be prepared by a mold casting method, or may be prepared by compacting ceramic powder. The ceramic sintered plate has an electrode 22 therein. Next, a plug placement hole 50 is formed to vertically penetrate the ceramic sintered plate while avoiding the electrode 22. The plug placement hole 50 can be formed by machining. Further, a plurality of protrusions 21b and a seal band 21a are formed on the upper surface of the ceramic sintered plate by laser processing or the like. The plurality of protrusions 21b and the seal band 21a may be formed after the ceramic substrate 20 and the base plate 30 are joined.

The base plate 30 includes a coolant passage 32 and a gas hole 34. The gas hole 34 has a large diameter portion 34a facing the upper surface 31. The base plate 30 including the refrigerant passage 32 can be manufactured by, for example, joining a plurality of MMC plate members, in which grooves or holes corresponding to the refrigerant passage 32 are formed, by machining using a method such as TCB (Thermal Compression Bonding). The gas holes 34 can be formed by machining the base plate 30 after the refrigerant passages 32 have been formed. The metal bonding material 90 includes a through hole 92 at a position facing the large diameter portion 34a of the gas hole 34. The through hole 92 can be formed by machining.

Subsequently, a metal bonding material 90 is sandwiched between the lower surface 23 of the ceramic substrate 20 and the upper surface 31 of the base plate 30 to form a laminate. At this time, it is preferable to laminate them such that the plug placement hole 50 of the ceramic substrate 20, the through hole 92 of the metal bonding material 90, and the gas hole 34 of the base plate 30 are coaxial. Then, the laminate is pressurized and bonded at a temperature no higher than the solidus temperature of the metal bonding material 90 (for example, the temperature 20° C. lower than the solidus temperature or more and no higher than the solidus temperature), and then returned to room temperature (TCB). Thereby, the metal bonding material 90 and the through hole 92 become the bonding layer 40 and the through hole 42, respectively, and a bonded body 94 in which the ceramic substrate 20 and the base plate 30 are bonded by the bonding layer 40 is obtained (FIG. 6B). The metal bonding material 90 preferably has a thickness of approximately 100 μm (for example, 80 to 240 μm).

Next, a plug 55 having a size and shape that can fit into the plug placement hole 50 is prepared (FIG. 4B). The height of the plug 55 is the same as the depth of the plug placement hole 50. Next, the plug 55 is press-fitted into the plug placement hole 50 from the upper opening 50a of the ceramic substrate 20 toward the lower opening 50b. Alternatively, a male threaded portion is formed on the outer peripheral surface 55e of the plug 55, which has been formed in advance by firing or the like, and a female threaded portion is formed on the inner peripheral surface 50c of the plug placement hole 50, and the plug 55 may be installed by screwing and inserting the plug 55 into the plug placement hole 50 so that the male threaded portion of the plug 55 and the female threaded portion of the plug placement hole 50 are screw fitted together. Thereafter, the member 10 for a semiconductor manufacturing equipment is completed by appropriately going through processes such as adjusting the overall shape (FIG. 4C).

### DESCRIPTION OF REFERENCE NUMERALS

10: Member for semiconductor manufacturing equipment
20: Ceramic substrate
21: Upper surface
21a: Seal band
21b: Protrusion
21c: Reference surface
21d: Recess
22: Electrode
23: Lower surface
30: Base plate
31: Upper surface
32: Refrigerant passage
33: Lower surface
34: Gas hole
34a: Large diameter portion
40: Bonding layer
42: Through hole
50: Plug placement hole
50a: Upper opening
50b: Lower opening
50c: Inner peripheral surface
55: Plug
55a: Upper end surface
55a1: Upper end opening
55b: Lower end surface
55b1: Lower end opening
55c: Dense body
55d: Gas passage
55d1: Surface
55e: Outer peripheral surface
55f: Upper end portion
55f1: Side surface
55f2: Side surface opening
60: Gas supply path
64a: Ring portion
64b: Gas introduction portion
64c: Distribution section
90: Metal bonding material
92: Through hole

1. A member for a semiconductor manufacturing equipment, comprising:
a ceramic substrate having an upper surface on which a wafer is to be placed and a lower surface; a plug placement hole that vertically penetrates the ceramic substrate; and a plug embedded in the plug placement hole;
wherein the plug is composed of a dense body, comprising an upper end surface exposed on a side of the upper surface, a lower end surface exposed on a side of the lower surface, and a gas passage that penetrates an inside of the dense body and extends from an upper end opening provided on the upper end surface to a lower end opening provided on the lower end surface; and
wherein a maximum height D₁ in the vertical direction from the upper end opening to a surface of the gas passage, and a maximum height D₂ in the vertical direction from the lower end opening to the surface of the gas passage satisfies a relationship: D₁<D₂.

2. The member for a semiconductor manufacturing equipment according to claim 1, wherein a relationship: 0.1≤D₁/D_{2≤0.9} is satisfied.

3. The member for a semiconductor manufacturing equipment according to claim 1, wherein the maximum height D₁ is 10 to 300 μm.

4. The member for a semiconductor manufacturing equipment according to claim 1, wherein the maximum height D₂ is 50 to 500 μm.

5. The member for a semiconductor manufacturing equipment according to claim 1, wherein taking a coordinate axis in the vertical direction, and assuming a coordinate value of the upper end surface of the plug is 0, and a coordinate value of the lower end surface is H, a height D of the gas passage in the vertical direction satisfies a relationship: D≥1.5 D₁ at least within a range of coordinate value from 0.5×H to 1.0×H.

6. The member for a semiconductor manufacturing equipment according to claim 5, wherein the height D of the gas passage in the vertical direction satisfies a relationship: D₁≤D<1.5 D₁ at least within a range of coordinate value from 0 to less than 0.1×H.

7. The member for a semiconductor manufacturing equipment according to claim 1, wherein the plug comprises a plurality of gas passages, and for all of the plurality of gas passages, the relationship D₁<D₂ is satisfied.

8. The member for a semiconductor manufacturing equipment according to claim 1, wherein a fracture toughness (KIC) of a part of the plug composed of the dense body is larger than a fracture toughness (KIC) of the ceramic substrate.

9. A member for a semiconductor manufacturing equipment, comprising:
a ceramic substrate having an upper surface on which a wafer is to be placed and a lower surface; a plug placement hole that vertically penetrates the ceramic substrate; and a plug embedded in the plug placement hole;
wherein the plug is composed of a dense body, comprising an upper end portion having an upper end surface exposed on a side of the upper surface, a lower end surface exposed on a side of the lower surface, and a gas passage that penetrates an inside of the dense body and extends from a side surface opening provided on a side surface of the upper end portion to a lower end opening provided on the lower end surface.

10. The member for a semiconductor manufacturing equipment according to claim 9, wherein a concave portion is formed on the upper surface on which a wafer is to be placed, and the upper end portion of the plug protrudes from a bottom of the concave portion such that the side surface opening is exposed.

11. The member for a semiconductor manufacturing equipment according to claim 9, wherein a height D of the gas passage in the vertical direction is 10 to 300 μm.

12. The member for a semiconductor manufacturing equipment according to claim 9, wherein a fracture toughness (KIC) of a part of the plug composed of the dense body is larger than a fracture toughness (KIC) of the ceramic substrate.

13. The member for a semiconductor manufacturing equipment according to claim 9, wherein the plug comprises a plurality of gas passages, and each of the plurality of gas passages is a gas passage that penetrates the inside of the dense body and extends from the side surface opening provided on the side surface of the upper end portion to the lower end opening provided on the lower end surface.
